(19) United States
(12) Patent Application Publication
(10) Pub. No.: US 2012/0292658 A1
(43) Pub. Date: Nov. 22, 2012

(54) SEMICONDUCTOR OPTOELECTRONIC CONVERTING SYSTEM AND THE FABRICATING METHOD THEREOF

(75) Inventors: Jen-Shyan Chen, Hsinchu City (TW); Hsian-Lung Tan, Hsinchu City (TW)

(73) Assignee: NEOBULB TECHNOLOGIES, INC., Bandar Seri Begawan (BN)

(21) Appl. No.: 13/471,123

(22) Filed: May 14, 2012

(30) Foreign Application Priority Data
May 18, 2011 (TW) 100117385

(51) Int. Cl. H01L 33/48; H01L 31/18; H01L 31/02

(52) U.S. Cl. 257/99; 257/433; 438/26; 438/64; 257/E33.056; 257/E31.11

(57) ABSTRACT

The present invention discloses a semiconductor optoelectronic converting system and the fabricating method thereof, the system comprises a supporting module, a heat pipe, a power converting module and a heat-dissipating plate module. The main features of the present invention are that the supporting module has an accommodating space for disposing the heat pipe, and wherein the supporting module and the heat pipe have a common surface for disposing the power converting module thereon. Furthermore, the present invention further decreases the heat resistant therebetween and improves the heat conducting rate and further capable of becoming a rechargeable self-sufficiency lighting system.

This application claims the benefit of the filing date of Taiwan Patent Application No. 100117385, filed May 18, 2011, entitled “Semiconductor Optoelectronic Converting System And The Fabricating Method Thereof,” and the contents of which is hereby incorporated by reference in its entirety.

### BACKGROUND OF THE INVENTION

1. Field of the Invention

The present invention relates to an energy convening system and the fabricating method thereof, and more particularly, to an optoelectronic converting system with high heat-dissipating efficiency and the fabricating method thereof.

2. Description of the Prior Art

With the consumption of petroleum, the demand of alternative energy resources is increasing dramatically, such as solar energy, wind power, and hydraulic power, wherein the solar energy is the most readily available and abundant source of energy. However, not all of the incident light can be absorbed and converted to current completely by solar cells, during the solar energy conversion process. The efficiency of a solar cell depends on many factors. The first factor is probably the most obvious. The brighter the sunlight, the more there is for the solar cell to convert. Contrary to popular belief, the efficiency of a solar cell decreases with increasing temperature. Therefore, it is important to improve the heat-dissipation rates of solar cells.

On the other hand, energy conservation awareness is a growing trend. With the development of semiconductor light-emitting components, light-emitting diodes have become a brand-new light source with many advantages including lower energy consumption, longer lifetime, improved robustness, smaller size, and faster switching. So far, light-emitting diodes are used in applications as diverse as aviation lighting, automotive lighting, advertising, general lighting, and traffic signals. However, the efficiency of light-emitting diodes is still affected by heat dissipation.

In the prior art, the energy converting system can not improve the heat-dissipating efficiency and reduce the volume thereof at the same time. Therefore, developing a energy converting system with small size and high heat-dissipating efficiency is necessary, so as to improve the problems described above without expensive costs.

### SUMMARY OF THE INVENTION

Therefore, a scope of the invention is to provide a semiconductor optoelectronic converting system which comprises a supporting module, a heat pipe, and a power converting module. The supporting module comprises an upper surface and an accommodating space; the heat pipe has a first part, a second part, and an upper plane, wherein the first part is configured in the accommodating space, the second part is extended from the first part, and the upper plane is coplanar with the upper surface of the supporting module. The power converting module is mounted on the supporting module for disposing the power converting module on the upper plane of the heat pipe. Wherein, the supporting module comprises a first lateral part and a second lateral part. The first lateral part has a first surface, and the second lateral part has a second surface; wherein, the first lateral part and the second lateral part form the accommodating space, and the upper surface of the supporting module comprises the first surface of the first lateral part and the second surface of the second lateral part.

Moreover, the supporting module further comprises a connecting part, used for connecting the first lateral part with the second lateral part, wherein the connecting part has a third surface which is comprised in the upper surface of the supporting module, and the accommodating space is surrounded by the first lateral part, the second lateral part, and the connecting part.

In addition, the power converting module further comprises an object stage, a substrate, and a power converting element. The object stage has a top surface and a bottom surface, the top surface and the bottom surface have a first recession and a second recession respectively, and wherein the first recession and the second recession are connected with each other. The substrate comprises a bottom surface and a loading part, and the substrate is embedded into the second recession. The power converting element is configured on the loading part. Wherein, the bottom surface of the object stage and the bottom surface of the substrate are coplanar in essence.

In actual application, the power converting element is a light-emitting diode element or a solar cell component. Furthermore, the power converting module and the supporting module comprise a plurality of corresponding through holes respectively, so as to fasten the power converting module to the supporting module with screws.

Additionally, the semiconductor optoelectronic converting system of the present invention further comprises a heat-dissipating plate module, which comprises an inner surface, an outer surface, and a plurality of cooling fins configured to extend outward from the outer surface of the heat-dissipating plate module, wherein the heat pipe is configured on the inner surface of the heat-dissipating plate module. Meanwhile, the heat-dissipating plate module has a plurality of concave holes, and the supporting module comprises a plurality of corresponding through holes, so as to fasten the supporting module to the inner surface of the heat-dissipating plate module with screws.

In actual application, the semiconductor optoelectronic converting system of the present invention further comprises a thermal insulation module which is configured between the first part of the heat pipe and the heat-dissipating plate module. Moreover, the second part of the heat pipe further comprises at least one bending portions. And furthermore, the present invention can further comprise a fastening module which has a plurality of through holes for fastening the heat pipe to the inner surface of the heat-dissipating plate module.

Accordingly, the semiconductor optoelectronic converting system of the present invention is not only beneficial for assembly of heat pipe, but also can decrease the heat resistant therebetween and improves the heat conducting rate. Furthermore, the supporting module of the present invention has an accommodating space for disposing the heat pipe, and meanwhile, the supporting module and the heat pipe have a common surface for disposing the power converting module thereon. Therefore, the present invention is further capable of becoming a rechargeable self-sufficiency lighting system.

Many other advantages and features of the present invention will be further understood by the detailed description and the accompanying sheet of drawings.

### BRIEF DESCRIPTION OF THE APPENDED DRAWINGS

FIG. 1A is a schematic diagram illustrating a semiconductor optoelectronic converting system according to an embodiment of the invention.

FIG. 1B is a cross-section along line A-A of FIG. 1A illustrating a semiconductor optoelectronic converting system according to an embodiment of the invention.

FIG. 1C is a top view illustrating a semiconductor optoelectronic converting system according to an embodiment of the invention.

FIG. 2A is a three dimensional view illustrating a supporting module according to an embodiment of the invention.

FIG. 2B is a front view illustrating a supporting module according to an embodiment of the invention.

FIG. 2C is a schematic diagram illustrating a supporting, module according to another embodiment of the invention.

FIG. 3 is an assembly diagram illustrating a supporting module and a heat pipe according to another embodiment of the invention.

FIG. 4A is a schematic diagram illustrating a heat pipe according to another embodiment of the invention.

FIG. 4B is a schematic diagram illustrating a heat pipe according to another embodiment of the invention.

FIG. 5A is a top view illustrating a power converting module according to an embodiment of the invention.

FIG. 5B is a cross-section along line Z-Z of FIG. 5 illustrating a power converting module according to an embodiment of the invention.

FIG. 6 is a flowchart illustrating a fabricating method of semiconductor optoelectronic converting system according to an embodiment of the invention.

To facilitate understanding, identical reference numerals have been used, where possible to designate identical elements that are common to the figures.

### DETAILED DESCRIPTION OF THE INVENTION

The invention discloses a semiconductor optoelectronic converting system which comprises a supporting module, a heat pipe, and a power converting module. The power converting module can be used for receiving optical energy or electrical energy to generate electrical energy or optical energy, and the thermal energy produced during the process can be conducted to a heat-dissipating plate module through the supporting module and the heat pipe so as to dissipate heat. Wherein, the main features of the present invention are that the supporting module has an accommodating space for disposing the heat pipe, and the supporting module and the heat pipe have a common surface for disposing the power converting module thereon.

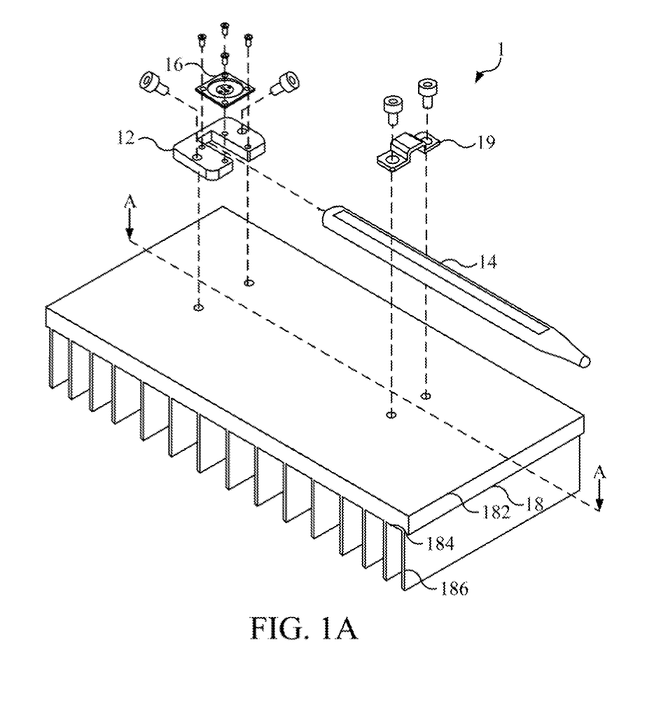

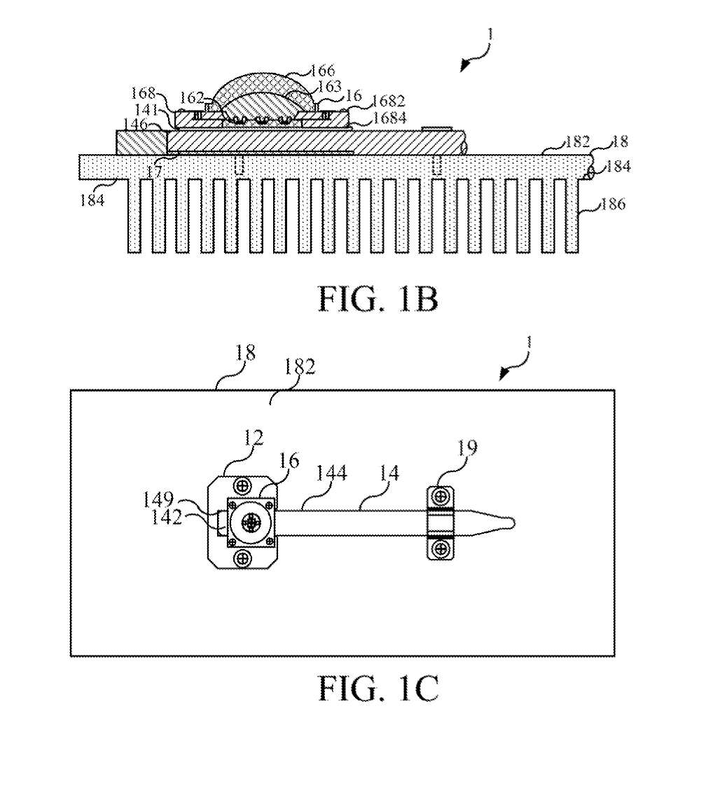

Please refer to FIG. 1A to 1C. FIG. 1A is a schematic diagram illustrating a semiconductor optoelectronic converting system according to an embodiment of the invention. FIG. 1B is a cross-section along line A-A of FIG. 1A illustrating a semiconductor optoelectronic converting system according to an embodiment of the invention. FIG. 1C is a top view illustrating a semiconductor optoelectronic converting system according to an embodiment of the invention. As shown in FIG. 1A to 1C, the present invention comprises a supporting module 12, a heat pipe 14, a power converting module 16, and a heat-dissipating plate module 18. The detailed descriptions of these components are illustrated as follows.

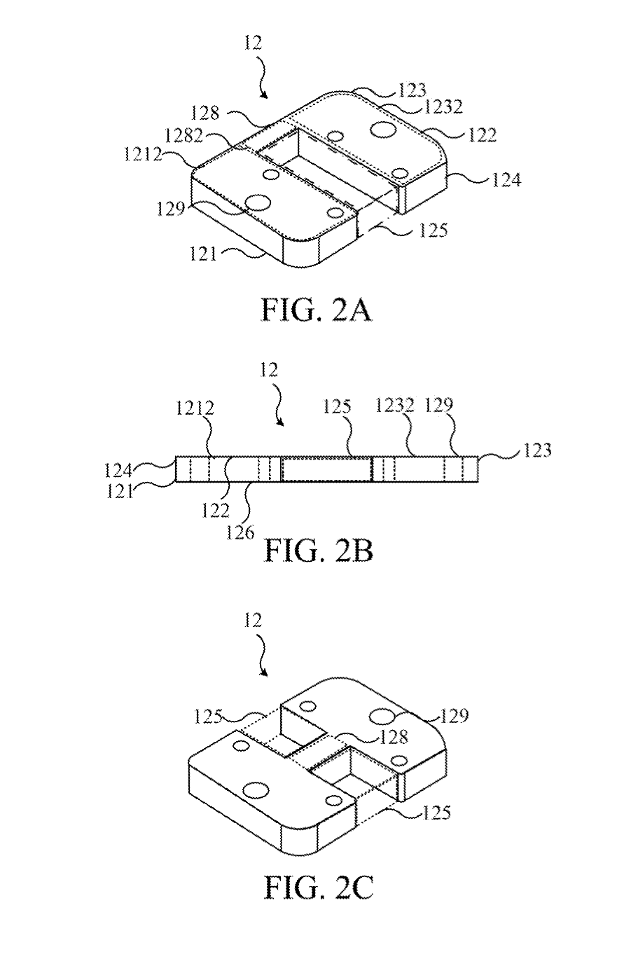

Please refer to FIGS. 1A, 2A, and 2B. FIG. 2A is a three dimensional view illustrating a supporting module according to an embodiment of the invention. FIG. 2B is a front view illustrating a supporting module according to an embodiment of the invention.

In this embodiment, the supporting module 12 comprises a first lateral part 121 and a second lateral part 123. The first lateral part 121 has a first surface 1212, and the second lateral part 123 has a second surface 1232, wherein the first lateral part and the second lateral part form an accommodating space 125 (as the dash line in FIG. 2A), and the accommodating space 125 is used for disposing the heat pipe 14. To be noticed, the supporting module 12 and the heat pipe 14 may be joined together with a jointing material. The jointing material mentioned above is a tin solder, including but not limited to, Cu, Ag, Pb, or other jointing materials with high thermal conductivity.

The supporting module 12 comprises an upper surface 122, a bottom surface 126, and a lateral surface 124. The bottom surface 126 of the supporting module 12 corresponds to the upper surface 122. The upper surface 122 of the supporting module 12 comprises the first surface 1212 of the first lateral part 121 and the second surface 1232 of the second lateral part 123. That is to say, the first surface 1212 and the second surface 1232 are coplanar in essence and form a common surface. Moreover, the supporting module further comprises a connecting part 128 between the first lateral part 121 and the second lateral part 123. The connecting part 128 is used for connecting the first lateral part 121 with the second lateral part 123, and the connecting part 128 has a third surface 1282 which is comprised in the upper surface 122 of the supporting module 12. The third surface 1282, the first surface 1212 and the second surface 1232 are coplanar in essence and form a common surface. Additionally, the accommodating space 125 is surrounded by the first lateral part 121, the second lateral part 123, and the connecting part 128.

To be noticed, the supporting module 12 and the heat pipe 14 may be joined together with a jointing material. The jointing material mentioned above can comprise including but not limited to, Sn, Cu, Ag, Pb, or other jointing materials with high thermal conductivity. In the embodiment, the supporting module 12 further comprises a plurality of through holes 129, wherein these through holes 129 correspond with the through holes of the power converting module 16, so as to fasten the power converting module 16 to the upper surface 122 of the supporting module 12. Furthermore, the heat-dissipating plate module 18 has a plurality of concave holes corresponding with these through holes 129, so as to fasten the supporting module 12 to the inner surface 182 of the heat-dissipating plate module 18.

Please refer to FIG. 1A to 1C again. In the embodiment, the object stage 168 of the power converting module 16 and the supporting module 12 comprise a plurality of corresponding through holes 129 respectively, so as to fasten the power converting module 16 to the supporting module 12 with screws. To be noticed, the present invention is not limited to this form, the through holes 129 and screws can be substituted by other fixation fasteners.

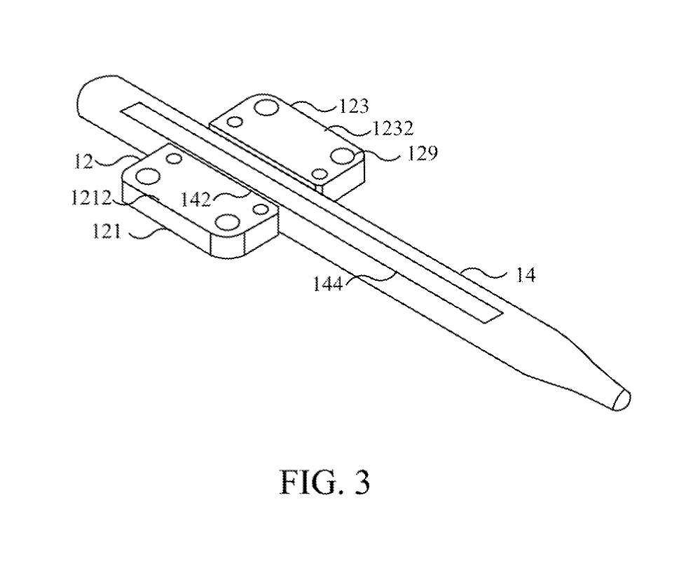

Please refer to FIG. 3. FIG. 3 is an assembly diagram illustrating a supporting module and a heat pipe according to another embodiment of the invention. In this embodiment, the connecting part 128 is omitted, and the heat pipe 14 is clamped between the first lateral part 121 and the second lateral part 123. To be noticed, the first surface 1212 of the first lateral part 121 and the second surface 1232 of the second lateral part 123 are coplanar in essence (in a horizontal configuration), and therefore, they can be seen as the upper surface 122 of the supporting module 12.

In the embodiment, the supporting module 12 has an accommodating space 125, but is not limited to this form. Please refer to FIG. 2C. FIG. 2C is a schematic diagram illustrating a supporting module according to another embodiment of the invention. As shown in FIG. 2C, each lateral surface 124 of the supporting module 12 may be used for forming the accommodating space 125.

Please refer to FIG. 1A to 1C again. In the embodiment, the heat pipe 14 of the present invention comprises a phase-change material and a capillary structure. Wherein the phase-change material can absorb heat and convert to gas, so as to enhance the thermal conduction capability with the phase-change mechanism. In addition, the heat pipe 14 has a first part 142, a second part 144, an upper plane, a bottom plane, and an end part 149.

The first part 142 is configured in the accommodating space 125, the second part 144 is extended from the first part 142, and the upper plane is coplanar with the upper surface 122 of the supporting module 12. Moreover, the end part 149 is formed at the distal end of the first part 142, and the end part 149 is joined with the supporting module 12 by the jointing material (not shown in figures). In this embodiment, the jointing material mentioned above is a tin solder, but is not limited to this material. Additionally, the first part 142 represents the part of the accommodating space 125 of the supporting module 12 where the heat pipe 14 configured on. To be noticed, the upper plane mentioned above is used for providing a place for the power converting module 16 to configure on, so as to increase the contact area of the heat pipe 14 and the power converting module 16, and further enhance the thermal conduction capability. Due to the upper plane is coplanar with the upper surface 122 of the supporting module 12, the gap clearance can be avoided to exist between the heat pipe 14 and the power converting module 16.

In the embodiment, the bottom plane of the heat pipe 14 is used for joining the heat pipe 14 to the inner surface 182 of the heat-dissipating plate module 18 tightly and further maximizing the contact area thereof. However the bottom plane is not a necessary component of the heat pipe 14, and the bottom plane can be replaced by configuring a groove which has a corresponding shape of the heat pipe 14 on the heat-dissipating plate module 18. Hence, the bottom plane can be omitted depending on demands.

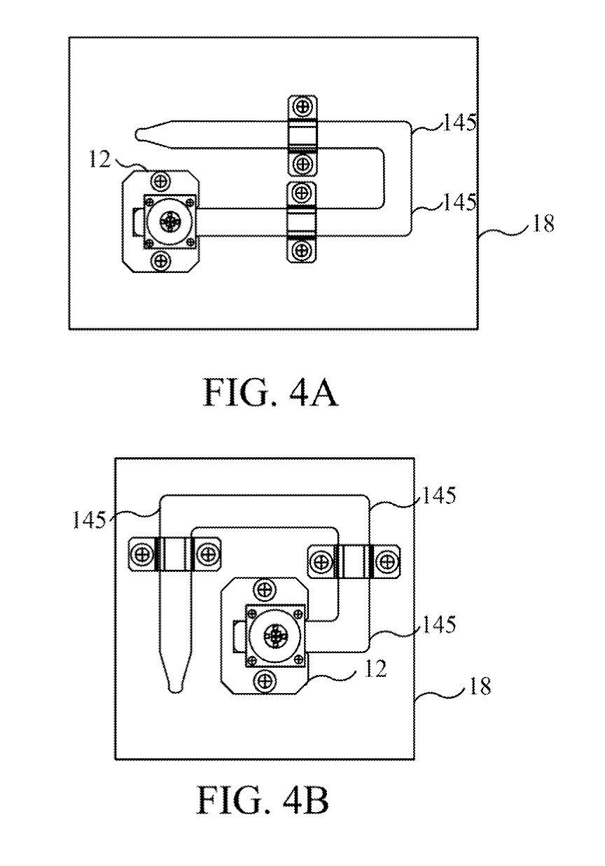

Furthermore, the second part 144 of the heat pipe 14 is extended from the first part 142. In the embodiment, the shape of the second part 144 is a straight line, but is not limited thereto. Please refer to FIGS. 4A and 4B. FIG. 4A is a schematic diagram illustrating a heat pipe according to another embodiment of the invention. FIG. 4B is a schematic diagram illustrating a heat pipe according to another embodiment of the invention. As shown in FIG. 4A, the heat pipe 14 comprises two bending portions 145, but is not limited to this structure, the number of the bending portions 145 is adjusted according to demands. To be noticed, the bending portions 145 are used for increasing the intensity of the heat pipe 14 on the heat-dissipating plate module 18. Wherein, FIGS. 4A and 4B disclosure the heat pipe 14 with two and three bending portions 145 respectively, and the heat pipe 14 is arranged in spiral form.

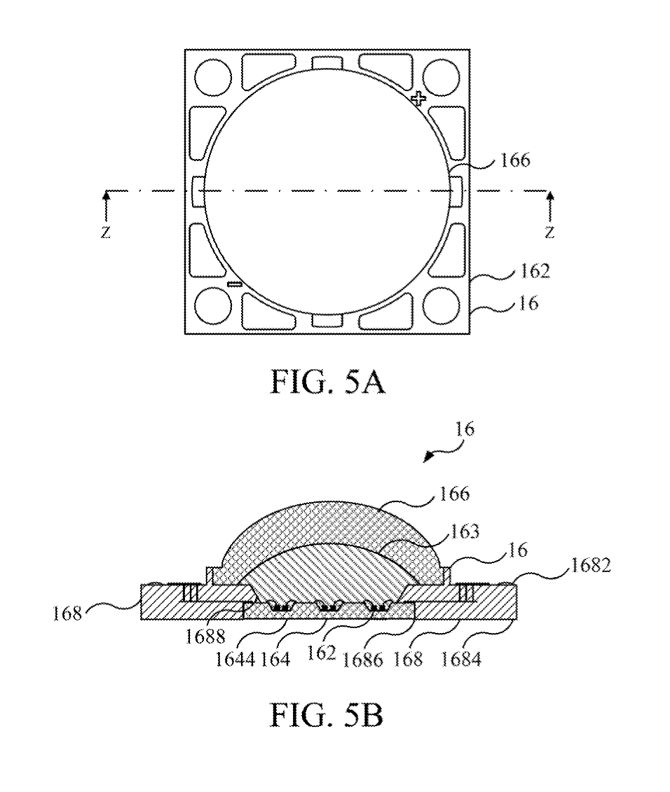

Please refer to FIGS. 1B, 5A, and 5B. FIG. 5A is a top view illustrating a power converting module according to an embodiment of the invention. FIG. 5B is a cross-section along line Z-Z of FIG. 5 illustrating a power converting module according to an embodiment of the invention. In this embodiment, the power converting module 16 comprises a power converting element 162, a substrate 164, a lens 166, and an object stage 168. Wherein, the power converting module 16 is mounted on the supporting module 12 for disposing the power converting module 16 on the upper plane of the heat pipe 14.

The object stage 168 has a top surface 1682 and a bottom surface 1684 which represent the surface of the power converting module 16 which emits the incident or emergent light and the corresponding surface thereof respectively. Wherein, the top surface 1682 has a first recession 1686; the bottom surface 1684 has a second recession 1688; and the first recession 1686 and the second recession 1688 are connected with each other. Moreover, the substrate 164 is embedded into the second recession 1688, and the surface of the substrate 164 can further comprise a plurality of recessions, and each recession has a reflecting layer (not shown in figures) for configuring the power converting element 162. In the embodiment, the diameter of the connecting portion of the first recession 1686 and the second recession 1688 is smaller than the diameter of the first recession 1686. Therefore, the second recession 1688 has a projecting part connected with the substrate 164. Furthermore, the projecting part can fix the substrate 164 and increase the adhesion area between the substrate 164 and the second recession 1688 to increase the adhesive ability therebetween. Additionally, an adhesive agent can fill between the substrate 164 and the second recession 1688, so as to enhance the fixation. At the same time, substrate 164 can be fixed with the help of the object stage 168.

In addition, the object stage 168 can be fixed on the supporting module 12 with several screws, so that the substrate 164 can compress the heat conduction phase-change material 141 and the power converting module 16 can be mounted on the upper plane 146 of the heat pipe 14. Moreover, the substrate 164 has a bottom surface 1644 which is coplanar with the bottom surface 1684 of the object stage 168. Therefore, the heat conduction phase-change material 141 can fill fully between the substrate 164 and the upper plane 164 of the heat pipe 14. To be more precise, the heat conduction phase-change material 141 is not a necessary component. In an embodiment, the power converting module 16 can be configured on the upper plane 146 of the heat pipe 14 directly. That is to say, the substrate 164 of the power converting module 16 is contacted to the upper plane 146 of the heat pipe 14 directly, therefore, the heat generated from the power converting module 16 can be dissipated rapidly by the heat pipe 14.

In the embodiment, the heat conduction phase-change material 141 can fill between the substrate 164 of the power converting module 16 and the upper plane 146 of the heat pipe 14, so as to decrease the interface thermal resistance therebetween. To be noticed, the fixation method between the supporting module 12 and the object stage 168 is not limited to this embodiment. More precisely, the supporting module 12 and the object stage 168 can be fixed with other conventional manner or fixation structures. Additionally, the power converting module 16 can further comprise the power converting element 162 which can convert electrical energy to optical energy and the power converting element 162 which can convert optical energy to electrical energy at the same time. With adding an electric storing module to the present invention, the semiconductor optoelectronic converting system is capable of becoming a rechargeable self-sufficiency lighting system. Wherein, the power converting element 162 is a light-emitting diode element or a solar cell component.

In this embodiment, the power converting element 162 is a light-emitting diode chip mounted on the substrate 164 (but is not limited to this), and used for convert electrical energy to optical energy; the power converting element 162 can be a solar cell chip used for convert optical energy to electrical energy. The power converting element 162 is wire-bonded to the electrode of the object stage 168 through a metal wire, so as to transmit electrical power to the chip. After die bonding and wire bonding, the power converting element 162 and the metal wire may be sealed by the photic electronic packaging material 163 for protection. Wherein, the electronic packaging material 163 can be used for optical modulation. For example, when the profile of the electronic packaging material 163 becomes convex (as shown in FIG. 1B), the light rays can be focused to a single point by the electronic packaging material 163. Furthermore, the electronic packaging material 163 can include a phosphor powder for modulating the wavelength of light, when the present invention is used for converting the electrical energy to optical energy.

In the embodiment, the power converting module 16 further comprises a lens 166 configured on the object stage 168 (but is not limited to this), so the lens 166 can be located above the power converting element 162. The lens 166 may be configured on the supporting module 12 or the heat-dissipating plate module 18 depending on the demands. In order to meet the demand of optical modulation, the curvature of the lens 166 can be designed properly to converge or diverge light. In actual application, the lens 166 of the present invention is not limited to a common convex lens. The lens 166 of the embodiment may have an indentation at the center, so as to converge light to be circularity.

The heat-dissipating plate module 18 is made of metal, and used for loading the heat pipe 14 and the supporting module 12. The heat-dissipating plate module 18 comprises an inner surface 182 and an outer surface 184, wherein the inner surface 182 is jointed with the bottom surface 126 of the supporting module 12. Additionally, there are a plurality of the cooling fins 186 configured to extend outward from the outer surface 184 of the heat-dissipating plate module 18.

Wherein, the surface of the cooling fins 186 can comprise a plurality of protrusion structures (not shown in the figures) used for increasing the surface area thereof to enhance the heat-dissipating efficiency, and the horizontal cross sectional area of the bottom of the cooling fin 186 is smaller than the horizontal cross sectional area of the upper structure. Moreover, the central temperature of the cooling fins 186 is higher than the periphery thereof. Therefore, the cooling fins 186 may be arranged in mound-like permutation according to the length thereof, more precisely, the short cooling fins 186 are configured on the outside, so as to maximize the heat-dissipating efficiency at the center of the cooling fins 186.

Please refer to FIG. 1A to 1C, the heat-dissipating plate module 18 has a plurality of concave holes, and the supporting module 12 comprises a plurality of corresponding through holes 129, so as to fasten the supporting module 12 to the inner surface 182 of the heat-dissipating plate module 18 with screws. To be noticed, the present invention is not limited to this form, the through holes 129 and screws can be substituted by other fixation fasteners.

In addition, the present invention further comprises a thermal insulation module 17 which is configured between the first part 142 of the heat pipe 14 and the heat-dissipating plate module 18, and used for preventing heat to accumulate at the first part 142 of the heat pipe 14.

In this embodiment, the present invention further comprises a fastening module 19 which has a plurality of through holes 129 for fastening the heat pipe 14 to the inner surface 182 of the heat-dissipating plate module 18.

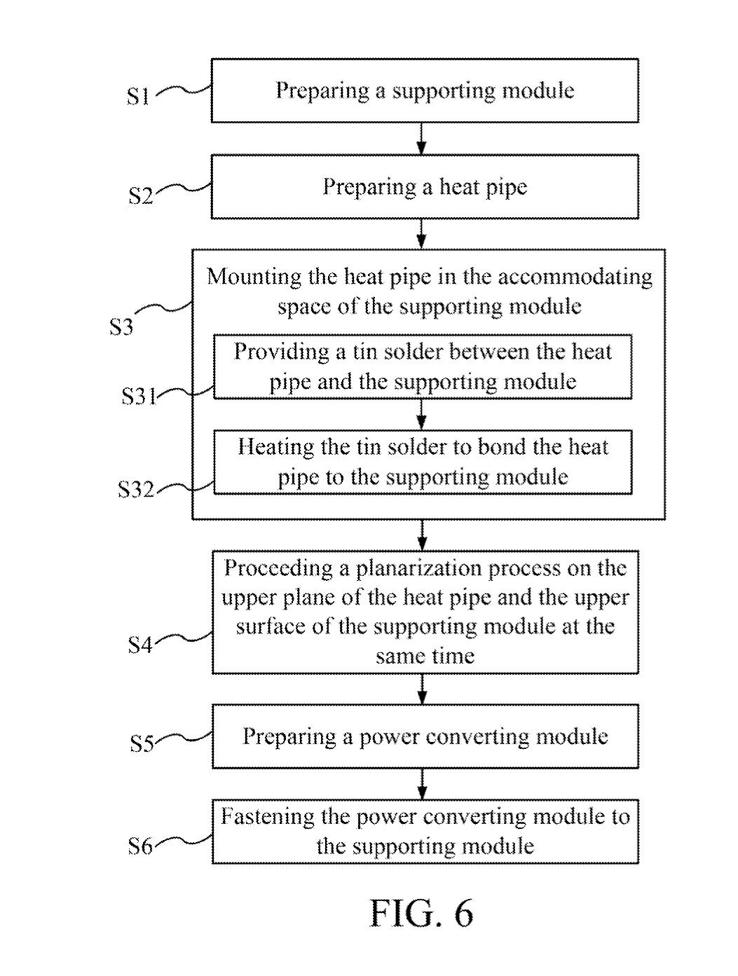

Please refer to FIG. 6. FIG. 6 is a flowchart illustrating a fabricating method of semiconductor optoelectronic converting system according to an embodiment of the invention. The semiconductor optoelectronic converting system described previously is used for receiving optical energy or electrical energy to generate electrical energy or optical energy. As shown in FIG. 6, the fabricating method comprises following steps: step S1: preparing a supporting module 12 having an upper surface 122 and an accommodating space 125. The supporting module 12 comprises an upper surface 122 and an accommodating space 125.

At step S2: preparing a heat pipe 14 having a first part 142, a second part 144, and an upper plane 146, and the second part 144 is extended from the first part 142. Wherein the heat pipe 14 comprises an end part 149 formed at the distal end of the first part 142, and the upper plane 146 is coplanar with the upper surface 122 of the supporting module 12.

At step S3: mounting the heat pipe 14 in the accommodating space 125 of the supporting module 12. In actual application, the step S3 comprises step S31: providing a tin solder between the heat pipe and the supporting module; and step S32: heating the tin solder to bond the heat pipe to the supporting module. In order to ensure the efficiency of thermal conductivity and heat dissipation, the upper surface 122 of the supporting module 12 and the heat pipe 14 should have a common surface for disposing the power converting module tightly thereon. Therefore, the present invention further proceeds to the step S4.

At step S4: proceeding a planarization process on the upper plane of the heat pipe 14 and the upper surface 122 of the supporting module 12 at the same time, so as to form a common surface.

In this embodiment, the fabricating method further comprises step S5: preparing a power converting module 16, wherein the power converting element 162 is a light-emitting diode element or a solar cell component; and step S6: fastening the power converting module 16 to the supporting module 12, so as to configure the power converting module 16 on the upper plane of the heat pipe 14.

In this embodiment, the supporting module 12 and the heat pipe 14 may be joined together with a jointing material. The jointing material mentioned above is a tin solder, including but not limited to, Cu, Ag, Pb, or other jointing materials with high thermal conductivity. Furthermore, the fixation method between the supporting module 12 and the heat pipe 14 is not limited to this form. More precisely, the supporting module 12 and the heat pipe 14 can be fixed with other conventional manner or fixation structures, such as welding.

The planarization process described above is a mechanical machining process which removing the material of the upper plane of the heat pipe 14 and the upper surface 122 of the supporting module 12 by polishing process, so as to form a common surface.

According to the above, the invention is to provide a semiconductor optoelectronic converting system and the fabricating method thereof. The present invention is not only beneficial for assembly of heat pipe, but also can decrease the heat resistant therebetween and improves the heat conducting rate. Furthermore, the supporting module of the present invention has an accommodating space for disposing the heat pipe, and meanwhile, the supporting module and the heat pipe have a common surface for disposing the power converting module thereon. Therefore, the present invention is further capable of becoming a rechargeable self-sufficiency lighting system.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A semiconductor optoelectronic converting system, comprising:
a supporting module, having an upper surface and an accommodating space;
a heat pipe, having a first part, a second part, and an upper plane; and
a power converting module, mounted on the supporting module for disposing the power converting module on the upper plane of the heat pipe;
wherein, the first part is configured in the accommodating space, the second part is extended from the first part, and the upper plane is coplanar with the upper surface of the supporting module.

2. The semiconductor optoelectronic converting system of claim 1, wherein the supporting module comprises:
a first lateral part, having a first surface; and
a second lateral part, having a second surface;
wherein, the first lateral part and the second lateral part form the accommodating space, and the upper surface of the supporting module comprises the first surface of the first lateral part and the second surface of the second lateral part.

3. The semiconductor optoelectronic converting system of claim 2, wherein the supporting module further comprises:
a connecting part used for connecting the first lateral part with the second lateral part, having a third surface which is comprised in the upper surface of the supporting module, and the accommodating space is surrounded by the first lateral part, the second lateral part, and the connecting part.

4. The semiconductor optoelectronic convening system of claim 1, wherein the power converting module comprises:
an object stage, having a top surface and a bottom surface, the top surface and the bottom surface having a first recession and a second recession respectively, and wherein the first recession and the second recession are connected with each other;
a substrate comprising a bottom surface and a loading part, and embedded into the second recession; and
a power converting element, configured on the loading part;
wherein, the bottom surface of the object stage and the bottom surface of the substrate are coplanar in essence.

5. The semiconductor optoelectronic converting system of claim 4, wherein the power converting element is a light-emitting diode element or a solar cell component.

6. The semiconductor optoelectronic converting system of claim 1, wherein the power converting module and the supporting module comprise a plurality of corresponding through holes respectively, so as to fasten the power converting module to the supporting module with screws.

7. The semiconductor optoelectronic converting system of claim 1, further comprising:
a heat-dissipating plate module which comprises an inner surface, an outer surface, and a plurality of cooling fins configured to extend outward from the outer surface of the heat-dissipating plate module, wherein the heat pipe is configured on the inner surface of the heat-dissipating plate module.

8. The semiconductor optoelectronic converting system of claim 7, wherein the heat-dissipating plate module has a plurality of concave holes, and the supporting module comprises a plurality of corresponding through holes, so as to fasten the supporting module to the inner surface of the heat-dissipating plate module with screws.

9. The semiconductor optoelectronic converting system of claim 7, further comprising a thermal insulation module configured between the first part of the heat pipe and the heat-dissipating plate module.

10. The semiconductor optoelectronic converting system of claim 1, wherein the second part of the heat pipe further comprises at least one bending portions.

11. The semiconductor optoelectronic converting system of claim 1, further comprising a fastening module which has a plurality of through holes for fastening the heat pipe to the inner surface of the heat-dissipating plate module.

12. The semiconductor optoelectronic converting system of claim 1, wherein there is a tin solder between the heat pipe and the supporting module for mounting the heat pipe in the accommodating space.

13. The semiconductor optoelectronic converting system of claim 1, further comprising a heat conduction phase-change material filling between the power converting module and the upper plane of the heat pipe.

14. A fabricating method for semiconductor optoelectronic converting system, comprising the following steps of:
S1: preparing a supporting module having an upper surface and an accommodating space;
S2: preparing a heat pipe having a first part, a second part, and an upper plane, the second part is extended from the first part;
S3: mounting the heat pipe in the accommodating space of the supporting module; and
S4: proceeding a planarization process on the upper plane of the heat pipe and the upper surface of the supporting module at the same time, so as to form a common surface.

15. The fabricating method of claim 14, wherein the step of mounting the heat pipe in the accommodating space further comprises:
S31: providing a tin solder between the heat pipe and the supporting module; and
S32: heating the tin solder to bond the heat pipe to the supporting module.

16. The fabricating method of claim 14, further comprising:
S5: preparing a power converting module, wherein the power converting element is a light-emitting diode element or a solar cell component; and
S6: fastening the power converting module to the supporting module, so as to configure the power converting module on the upper plane of the heat pipe.
